(19) United States
(12) Patent Application Publication
(10) Pub. No.: US 2006/0284254 A1
(43) Pub. Date: Dec. 21, 2006

(54) Pixel structures and methods for fabricating the same

(75) Inventors: Sheng-Chao Liu, Kaohsiung City (TW); Jian-Shen Yu, Hsinchu (TW); Chun-Sheng Li, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/246,467

(22) Filed: Oct. 7, 2005

(30) Foreign Application Priority Data
Jun. 20, 2005 (TW) 94120411

(51) Int. Cl. H01L 27/12

(52) U.S. Cl. 257/350

(57) ABSTRACT

Pixel structures and methods for fabricating the same are provided. The pixel structure comprises a thin film transistor formed on a substrate. The thin film transistor comprises a gate electrode and an active layer. The active layer comprises a source region and a drain region doped with a first dopant. A capacitor is formed on the substrate. The capacitor comprises a lower electrode and an upper electrode. The lower electrode is doped with a second dopant electrically connecting the source region. The first dopant and the second dopant are of different types.

This application claims the benefit of Taiwan application Serial No. 94120411, filed Jun. 20, 2005, the subject matter of which is incorporated herein by reference.

### BACKGROUND

The invention relates to pixel structures and methods for fabricating the same, and more particularly, to pixel structures with source/drain region not connected a lower electrode of capacitors and methods for fabricating the same.

Liquid crystal displays (LCDs) are among the most widely used flat panel displays. In LCDs, thin film transistors serve as active elements to control orientation of liquid crystal molecules and capacitors store charge storages to maintain image display.

FIG. 1 is a cross section of a conventional pixel structure, with a thin film transistor (TFT) region A and a capacitor region B, comprising a substrate 100, a buffer layer 110, an active layer 120a and lower electrode 120b, dielectric layer 130, gate electrodes 140a1 and 140a2, and upper electrode 140b, first insulating layer 150, signal line 160a, and a second metal layer 160b. Signal line 160a electrically contacts the source of the active layer 120a of the TFT via a contact plug 145a. The second metal layer 160b electrically contacts the lower electrode 120b via a contact plug 145b. A second insulating layer 170 covers the first insulating layer 150, the signal line 160a, and the second metal layer 160b. A pixel electrode 180 is disposed on the second insulating layer 170 and contacts the second metal layer 160b via a contact plug 165.

FIG. 2A is a plan view of the active layer 120a and the lower electrode 120b in FIG. 1. The active layer 120a and lower electrode 120b are made of the same continuous thin film, such as poly silicon. FIG. 1 is the cross section taken along line LL of FIG. 2A. FIG. 2B is a plan view of a doped active layer 120a and a doped lower electrode 120b, wherein shadow areas indicate doped regions.

FIGS. 1 to 2B depict a conventional method which shows active layer 120a and lower electrode are continuous, wherein the lower electrode of a capacitor is to improve capacitance. The critical dimensions of the active layer 120a and the lower electrode 120b, however, are quite different during fabrication, causing loading effect due to etching rates and profiles differences. The variations in critical dimensions between the thin film transistor and peripheral circuits increase, therefore, deteriorating performance consistency between the thin film transistor and peripheral circuits.

### SUMMARY

Accordingly, the invention provides pixel structures and methods for fabricating the same to ameliorate loading effect due to critical dimension variations and achieve more controllable device performance.

The invention also provides a pixel structure, comprising a thin film transistor formed on a substrate. The thin film transistor comprises a gate electrode and an active layer. The active layer comprises a source region and a drain region doped with a first dopant. A capacitor is formed on the substrate. The capacitor comprises a lower electrode and an upper electrode. The lower electrode is doped with a second dopant electrically connecting the source region. The first dopant and the second dopant are of different types.

The invention further provides a pixel structure, comprising a thin film transistor formed on a substrate. The thin film transistor comprises a gate electrode and an active layer. The active layer comprises a source region and a drain region. A capacitor is formed on the substrate. The capacitor comprises a lower electrode and an upper electrode. The source region and the drain region do not directly connect the lower electrode.

The invention further provides a method for fabricating a pixel structure, comprising forming a buffer layer on a substrate, an active layer and a lower electrode on the buffer layer, wherein the active layer comprises a source region and a drain region, doping a first dopant at the source region and the drain region and a second dopant at the lower electrode, wherein the first dopant and the second dopant are of different types, a dielectric layer on the active layer and the lower electrode, and at least one gate and an upper electrode on the dielectric layer, respectively corresponding to the active layer and the lower electrode.

The invention further provides a method for fabricating a pixel structure, comprising forming a buffer layer on a substrate, a semiconductor layer on the buffer layer, patterning the semiconductor to define an active layer and a lower electrode, wherein the active layer comprises a source region and a drain region not directly connecting the lower electrode, a dielectric layer on the active layer and the lower electrode and at least one gate and an upper electrode on the dielectric layer, respectively corresponding to the active layer and the lower electrode.

### DESCRIPTION OF THE DRAWINGS

The invention can be more fully understood by reading the subsequent detailed description in conjunction with the examples and references made to the accompanying drawings, wherein:

FIG. 1 is a cross section of a conventional pixel structure, having a thin film transistor (TFT) region A and a capacitor region B;

FIG. 2A is a plan view of the active layer 120a and the lower electrode 120b in FIG. 1;

FIG. 2B is a plan view of a doped active layer 120a and a doped lower electrode 120b, wherein shadow areas indicate doped regions;

FIGS. 3A-3C are cross sections of a first embodiment of forming a pixel structure;

FIG. 4A is a plan view of FIG. 3A taken along line L′L′ thereof;

FIG. 4B is a plan view of FIG. 3B taken along line L′L′ thereof, wherein shadow areas indicate doped regions;

FIGS. 5A-5C are cross sections of a second embodiment of forming a pixel structure;

FIG. 6A is a plan view of FIG. 5A taken along line L′L′ thereof; and

FIG. 6B is a plan view of FIG. 5B taken along line L′L′ thereof, wherein shadow areas indicate doped regions.

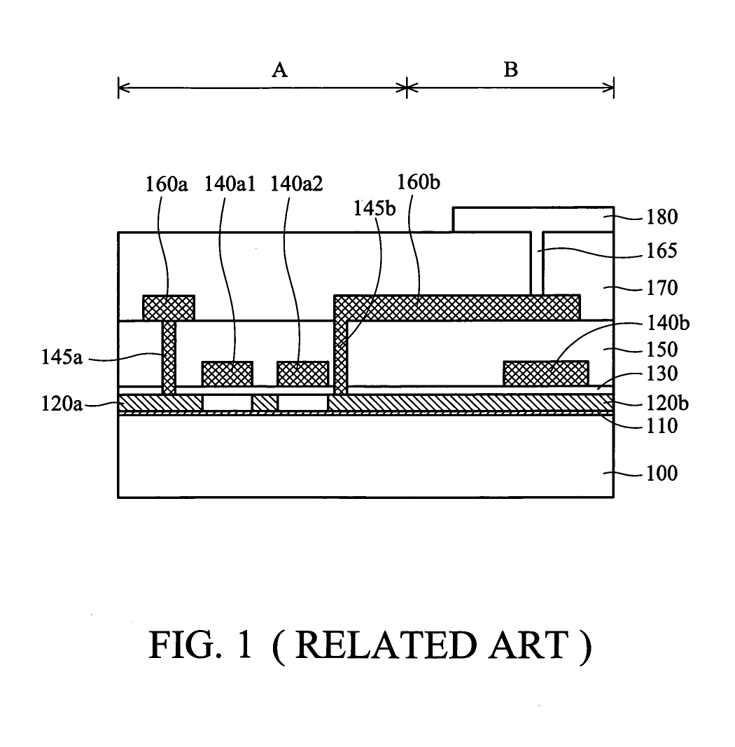

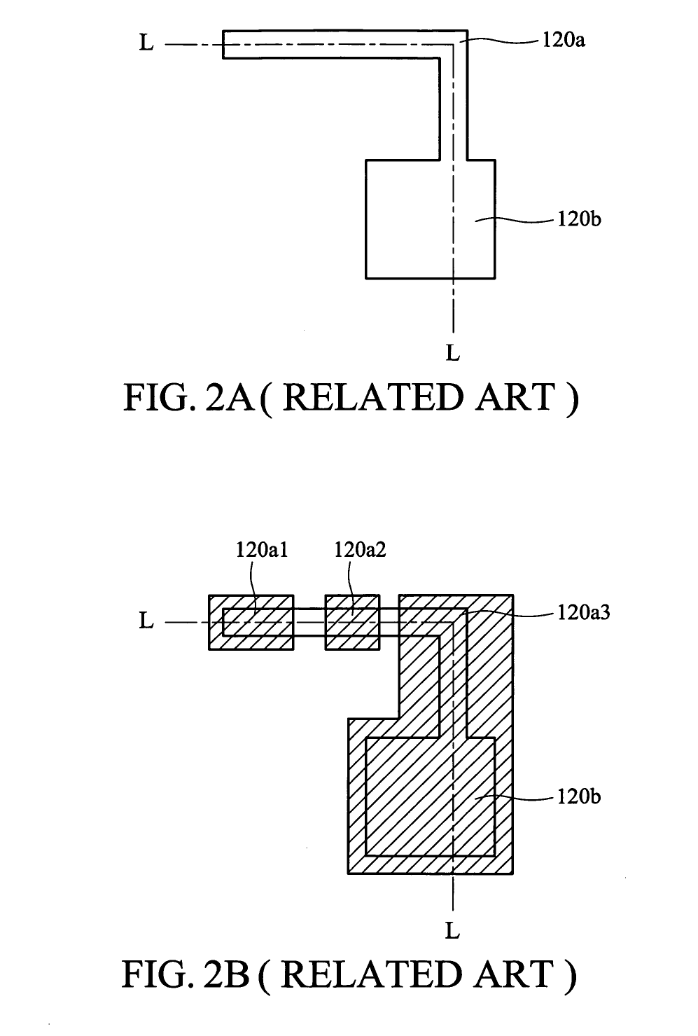

### DETAILED DESCRIPTION

### First Embodiment

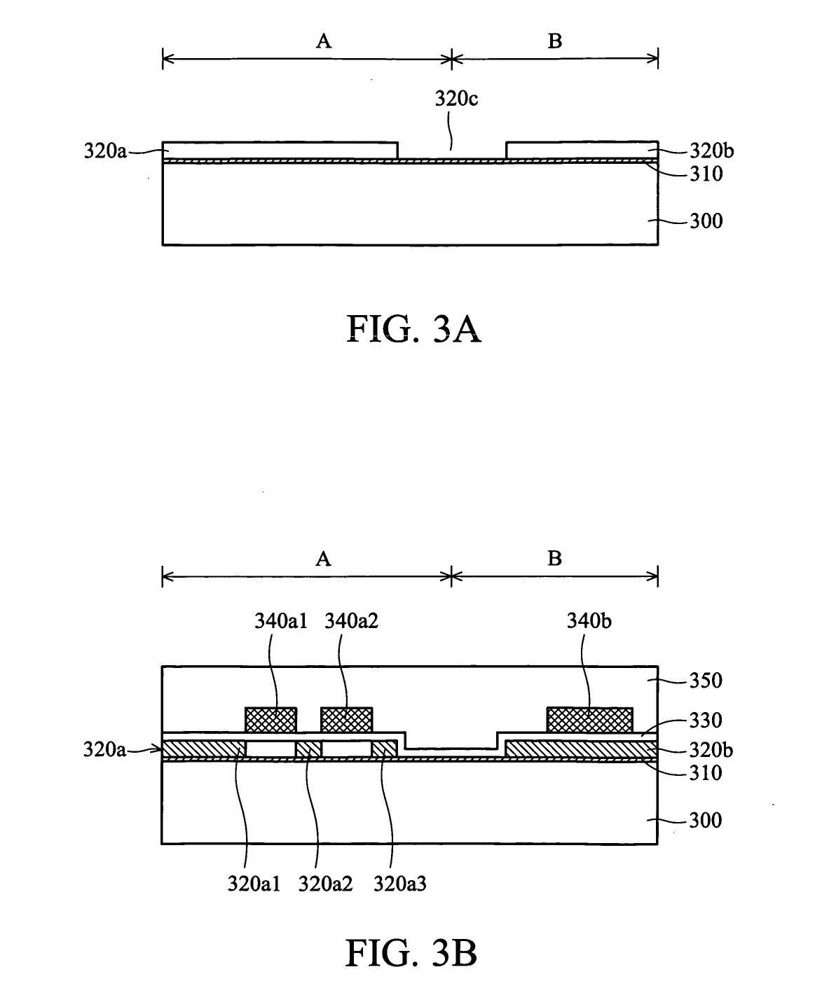

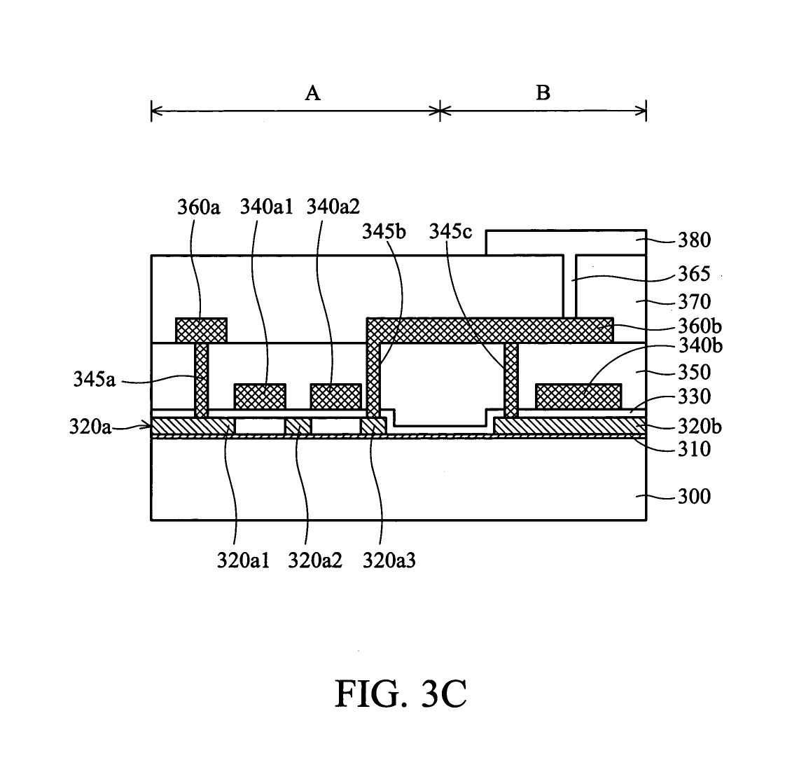

FIGS. 3A-3C are cross sections of a first embodiment of forming a pixel structure. FIG. 3A is a cross section of forming a patterned semiconductor layer with a thin film transistor (TFT) region A and a capacitor region B on a substrate 300. A buffer layer 310 is formed on a substrate 300 by chemical vapor deposition (CVD). The substrate 300 can comprise glass. The buffer layer 310 can comprise silicon oxide and/or silicon nitride.

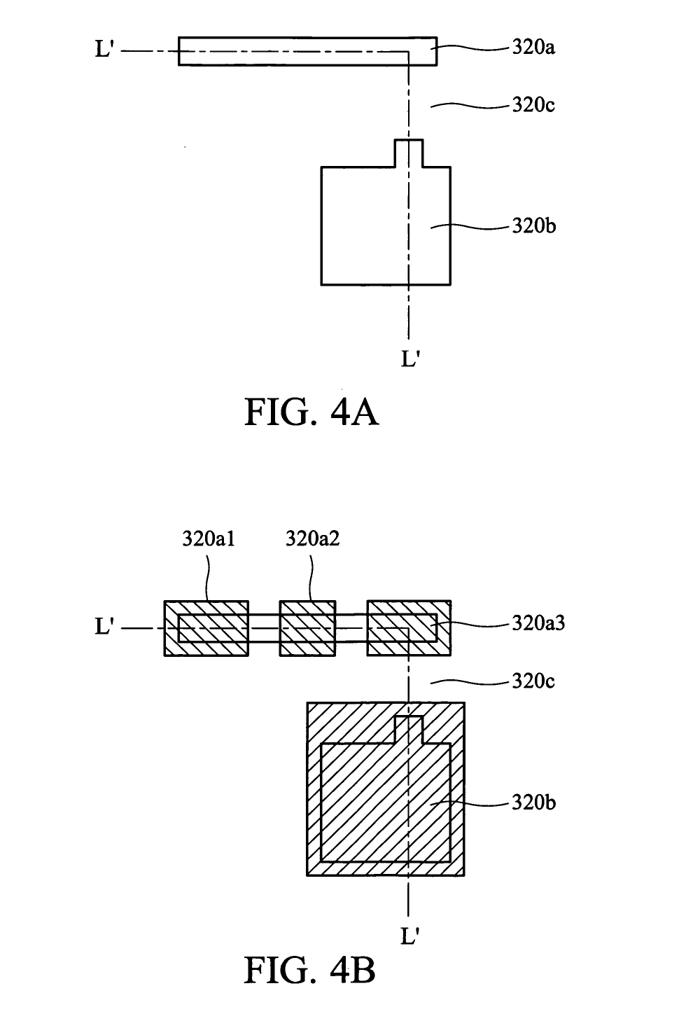

A semiconductor layer is subsequently formed on the buffer layer 310. The semiconductor layer is lithographically patterned into an active layer 320a, a lower electrode 320b, and an opening 320c. The active layer 320a and the lower electrode 320b are physically disconnected by way of opening 320c therebetween. FIG. 4A is a plan view of FIG. 3A which is a cross section taken along line L′L′ thereof. Disconnection between the active layer 320a and the lower electrode 320b can ameliorate loading effect. Critical dimensions are thus more controllable and device performance is also more consistent. The active layer 320a and the lower electrode 320b can be a poly silicon layer, preferably low temperature poly silicon (LTPS). For example, an amorphous silicon layer is formed by plasma enhanced chemical vapor deposition (PECVD) or low pressure chemical vapor deposition (LPCVD) on the buffer layer 310. The amorphous silicon layer is crystallized by laser annealing. Active layer 320a and lower electrode 320b are separated by etching.

Referring to FIG. 3B, the active layer 320a and the lower electrode 320b are separately doped. The active layer 320a is doped with a first dopant to form a source region 320a1, an intermediate region 320a2 and a drain region 320a3. The lower electrode 320b is doped with a second dopant. The first dopant and the second dopant are of different types depending on device requirements. FIG. 4B is a plan view of FIG. 3B which is the cross section taken along line L′L′ thereof. If the first dopant is a P-type dopant, the second dopant can be an N-type dopant. Alternatively, if the first dopant is an N-type dopant, the second dopant can be a P-type dopant. The N-type dopant comprises phosphor (P). The P type dopant comprises boron (B). The concentration of the N-type dopant is approximately in a range between 8×10¹² and 8×10¹⁶ atoms/cm³. The concentration of the P-type dopant is approximately in a range between 1×10¹³ and 1×10¹⁷ atoms/cm³. For example, a first mask (not shown) is formed above a portion of the active layer 320a and the lower electrode 320b. The source region 320a1, the intermediate region 320a2 and the drain region 320a3 are formed by a step of a first doping. The first mask is removed. A second mask (not shown) is subsequently formed above the active layer 320a. The lower electrode is formed by a step of a second doping. The dopant type of the source region 320a1, the intermediate region 320a2 and the drain region 320a3 different from that of the lower electrode can thus be achieved. Note that the doping sequence is not limited to that disclosed above.

A dielectric layer 330 is conformably formed on the active layer 320a, buffer layer 310, lower electrode 320b, separately serving as a gate dielectric layer on the active layer 320a and capacitor dielectric layer on the lower electrode 320b. The dielectric layer 330 can be silicon oxide formed by CVD. After the dielectric layer 330 is deposited, the quality of an interface between the active layer 320a and the dielectric layer 330 can be improved by annealing to activate dopant and removing excess hydrogen from the interface, thus, device performance can be improved.

Referring to FIG. 3B, a first metal layer is formed on the gate dielectric layer and the capacitor dielectric layer. The first metal layer is then lithographically etched into gate electrodes 340a1 and 340a2 and an upper electrode 340b. The first metal layer can comprise aluminum (Al), copper (Cu) nickel (Ni), molybdenum (Mo), and alloy thereof, formed by sputtering.

Referring to FIG. 3C, a first insulating layer 350 is formed on the gate electrodes 340a1 and 340a2, the upper electrode 340b, and the dielectric layer 330. Openings 345a, 345b, and 345c are formed to expose the source region 320a1, the drain region 320a3, and the lower electrode 320b. A conductive layer is filled into the openings 345a, 345b, and 345c, serving electrical contacts. A second metal layer is subsequently formed, comprising a signal line 360a electrically connecting the source region 320a1 via the contact in the opening 345a, and an electrode line 360b electrically connecting the drain region 320a3 and the lower electrode 320b via opening 345b and 345c respectively. The conductive layer in the openings 345a, 345b, and 345c and the second metal layer can be formed at the same step or at different steps. The second metal layer is preferably formed synchronously filling the openings 345a, 345b, and 345c. A second insulating layer 370 is subsequently formed on the first insulating layer 350 and the second metal layer. An opening 365 is then formed, exposing the electrode line 360b. A pixel electrode 380, is formed on the second insulating layer 370, filling the opening 365. The pixel electrode 380 electrically connects the electrode line 360b via the opening 365, and further electrically connects the source region 320a3 and the lower electrode 320b via opening 345b and 345c respectively.

In FIG. 3C, the invention provides a pixel structure comprising a thin film transistor (TFT) region A and a capacitor region B, in which the TFT region A is formed on a substrate 300. The thin film transistor in the TFT region A is a dual-gate structure comprising gate electrodes 340a1 and 340a2 and an active layer 320a formed by low temperature poly silicon (LTPS). The active layer 320a comprises a source region 320a1, an intermediate region 320a2, and a drain region 320a3, are doped with a first dopant. The capacitor in the capacitor region B is formed on the substrate 300, comprising a lower electrode 320b, an upper electrode 340b, and a dielectric layer 330 interposed therebetween. The lower electrode 320b is doped with a second dopant. The first dopant and the second dopant are of different types. The drain region 320a1, the intermediate region 320a2, and the source region 320a3 disconnect the lower electrode 320b physically. The pixel structure of the first embodiment can ameliorate the loading effect, achieving more controllable device performance.

### Second Embodiment

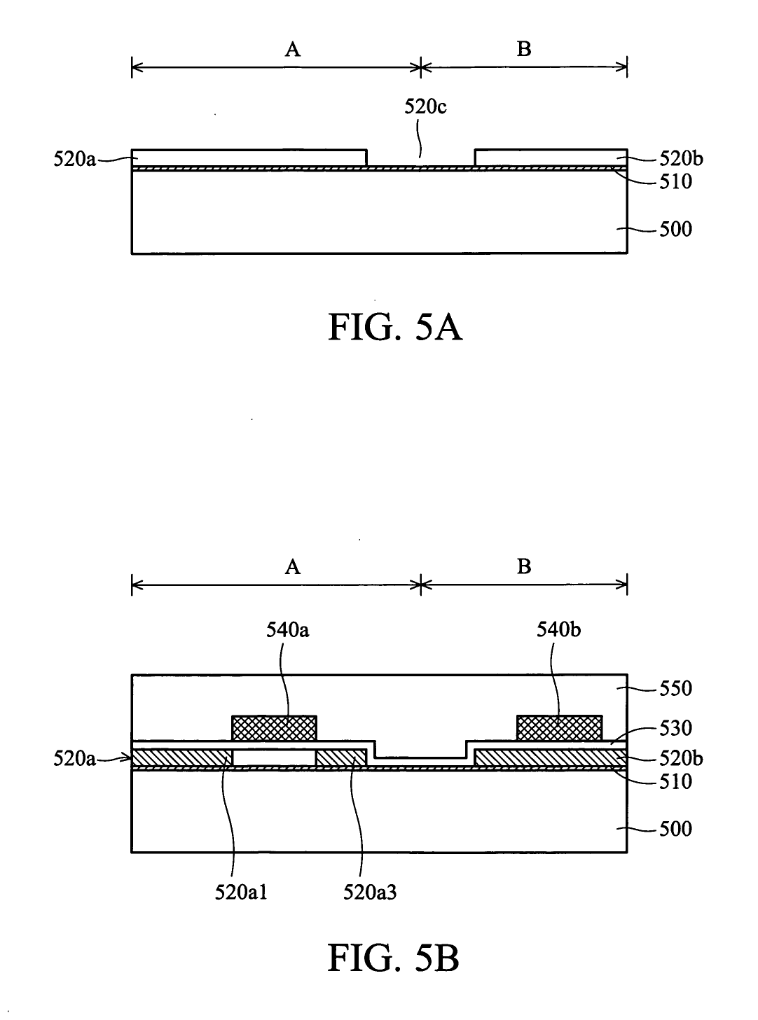

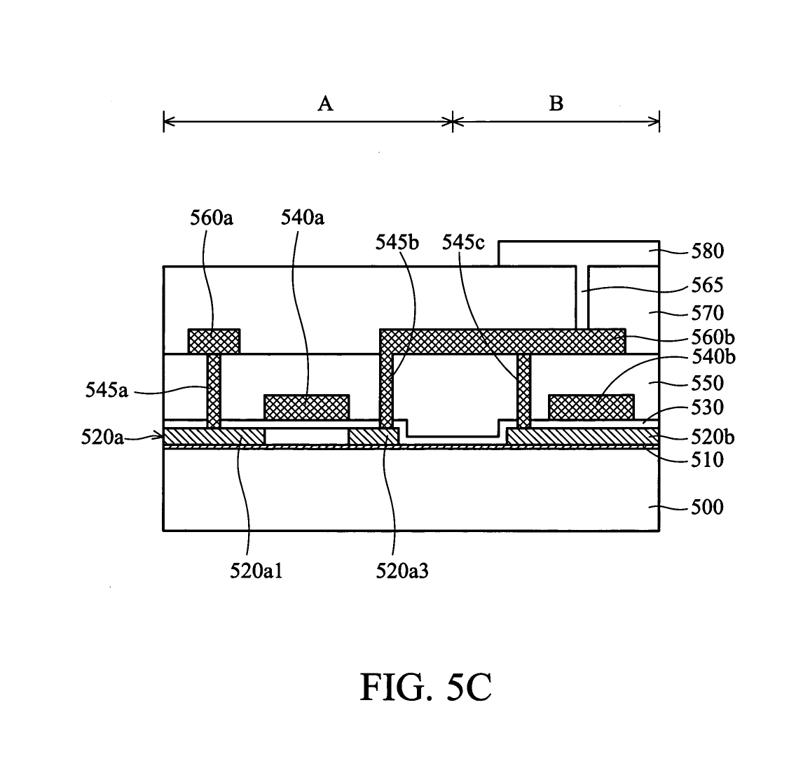

FIGS. 5A-5C are cross sections of a second embodiment of forming a pixel structure. FIG. 5A is a cross section of forming a patterned semiconductor layer with a thin film transistor (TFT) region A and a capacitor region B on a substrate 500. A buffer layer 510 is formed on the substrate 500 by chemical vapor deposition (CVD), for example. The substrate 500 can comprise glass. The buffer layer 510 can comprise silicon oxide and/or silicon nitride.

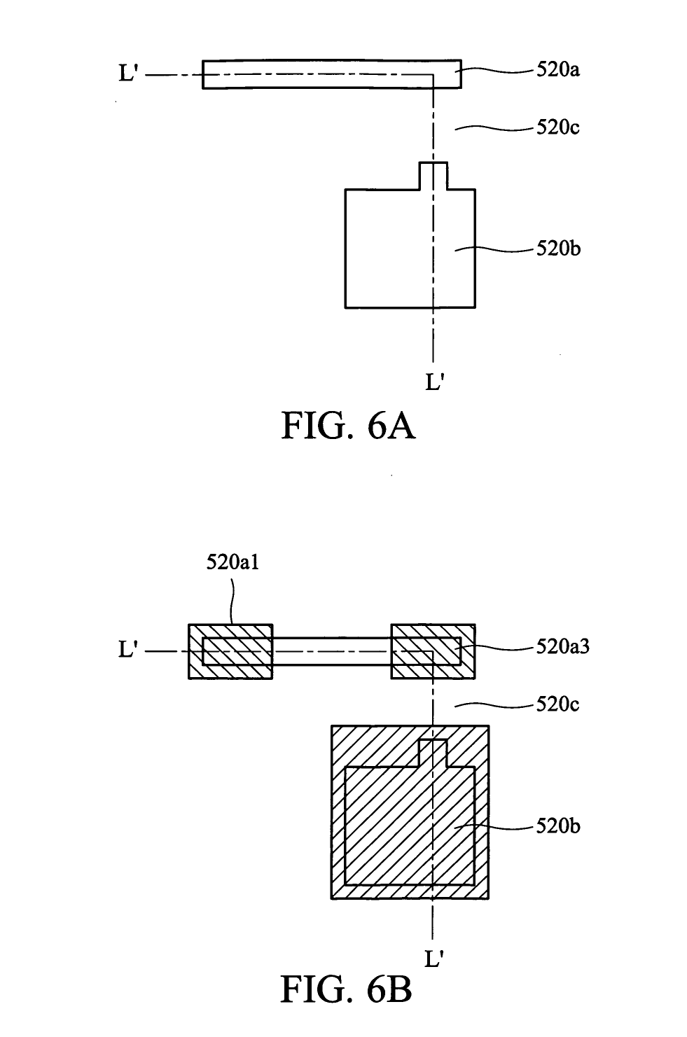

A semiconductor layer is subsequently formed on the buffer layer 510. The semiconductor layer is lithographically patterned into an active layer 520a, a lower electrode 520b, and an opening 520c. The active layer 520a and the lower electrode 520b are disconnected by way of the opening 520c therebetween. FIG. 6A is a plan view of FIG. 5A which is the cross section taken along line L′L′ thereof. Disconnection between the active layer 520a and the lower electrode 520b can ameliorate the loading effect. Thus, critical dimensions are more controllable and device performance is also more consistent. The active layer 520a and the lower electrode 520b can be an amorphous silicon layer. For example, an amorphous silicon layer is formed by plasma enhanced chemical vapor deposition (PECVD) or low pressure chemical vapor deposition (LPCVD) on the buffer layer 510, for example. The amorphous silicon layer is etched into an active layer 520a and a lower electrode 520b.

Referring to FIG. 5B, the active layer 520a and the lower electrode 520b are separately doped. The active layer 520a is doped with a first dopant to form a source region 520a1 and a drain region 520a3. The lower electrode 520b is doped with a second dopant. The first dopant and the second dopant are of different types depending on device requirements. FIG. 6B is a plan view of FIG. 5B which is the cross section taken along line L′L′ thereof. If the first dopant is a P-type dopant, the second dopant can be an N-type dopant. Alternatively, if the first dopant is an N-type dopant, the second dopant can be a P-type dopant. The N-type dopant comprises phosphor (P). The P type dopant comprises boron (B). The concentration of the N-type dopant is approximately in a range between 8×10¹² and 8×10¹⁶ atoms/cm³. The concentration of the P-type dopant is approximately in a range between 1×10¹³ and 1×10¹⁷ atoms/cm³. For example, a first mask (not shown) is formed above a portion of the active layer 520a and the lower electrode 520b. The source region 520a1 and the drain region 520a3 are formed by a step of a first doping. The first mask is removed. A second mask (not shown) is subsequently formed above the active layer 520a. The lower electrode 520b is formed by a step of a second doping. The dopant type of source region 520a1 and the drain region 320a3 different from that of the lower electrode 520b can thus be achieved. Note that the doping sequence is not limited to that disclosed above.

A dielectric layer 530 is conformably formed on the active layer 520a, buffer layer 510, lower electrode 520b, separately serving as a gate dielectric layer on the active layer 520a and a capacitor dielectric layer on the lower electrode 520b. The dielectric layer 530 can be silicon oxide formed by CVD. After the dielectric layer 530 is deposited, the quality of an interface between the active layer 520a and the dielectric layer 530 can be improved by annealing to activate dopant and removing excess hydrogen from the interface, thus, device performance can be improved.

Referring to FIG. 5B, a first metal layer is formed on the gate dielectric layer and the capacitor dielectric layer. The first metal layer is then lithographically etched into a gate electrode 540a and an upper electrode 540b. The first metal layer can comprise aluminum (Al), copper (Cu), nickel (Ni), molybdenum (Mo), and alloy thereof, formed by sputtering.

Referring to FIG. 5C, a first insulating layer 550 is formed on the gate electrode 540a, the upper electrode 540b, and the dielectric layer 530. Openings 545a, 545b, and 545c are formed to expose the source region 520a1, the drain region 520a3, and the lower electrode 520b. A conductive layer is filled into the openings 545a, 545b, and 545c, serving as electrical contacts. A second metal layer is subsequently formed, comprising a signal line 560a electrically connecting the source region 520a1 via the contact in the opening 545a, and an electrode line 560b electrically connecting the drain region 520a3 and the lower electrode 520b via opening 545b and 545c respectively. The conductive layer in the openings 545a, 545b, and 545c and the second metal layer can be formed in the same step or in different steps. The second metal layer is preferably formed synchronously filling the openings 545a, 545b, and 545c. A second insulating layer 570 is subsequently formed on the first insulating layer 550 and the second metal layer. An opening 565 is formed, exposing the electrode line 560b. A pixel electrode 580 is formed on the second insulating layer 570 and fills the opening 565. The pixel electrode 580 electrically connects the electrode line 560b via the opening 565, and further electrically connects the source region 520a3 and the lower electrode 520b.

FIG. 5C depicts the second embodiment of the invention, which provides a pixel structure comprising a thin film transistor (TFT) region A and a capacitor region B, in which the TFT region A is formed on a substrate 500. The thin film transistor in the TFT region A is a single-gate structure comprising gate electrode 540a and an active layer 520a made of an amorphous silicon. The active layer comprises a source region 520a1 and a drain region 520a3, doped with a first dopant. The capacitor in the capacitor region B is formed on the substrate 500, comprising a lower electrode 520b, an upper electrode 540b, and a dielectric layer 530 interposed therebetween. The lower electrode 520b is doped with a second dopant. The first dopant and the second dopant are of different types. The drain region 520a1 and the source region 520a3 are physically disconnected to the lower electrode 520b. The pixel structure of the first embodiment can ameliorate loading effect, achieving more controllable device performance.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A pixel structure, comprising:
a thin film transistor, formed on a substrate, comprising a gate electrode and an active layer, wherein the active layer comprises a source region and a drain region having a first dopant;
a dielectric layer formed between the gate electrode and the active layer; and
a capacitor, formed on the substrate, comprising:
a lower electrode, beneath the dielectric layer, having a second dopant and electrically connecting the source region; and
an upper electrode on the dielectric layer, wherein the first dopant and the second dopant are of different types.

2. The pixel structure as claimed in claim 1, wherein the first dopant is an N-type dopant and the second dopant is a P-type dopant.

3. The pixel structure as claimed in claim 2, wherein the N-type dopant comprises phosphorus.

4. The pixel structure as claimed in claim 2, wherein the P-type dopant comprises boron.

5. The pixel structure as claimed in claim 2, wherein the concentration of the N-type dopant is approximately in a range between 8×10¹² and 8×10¹⁶ atoms/cm³.

6. The pixel structure as claimed in claim 2, wherein the concentration of the P-type dopant is approximately in a range between 1×10¹³ and 1×10¹⁷ atoms/cm³.

7. The pixel structure as claimed in claim 1, wherein the first dopant is a P-type dopant and the second dopant is an N-type dopant.

8. The pixel structure as claimed in claim 7, wherein the N-type dopant comprises phosphorus.

9. The pixel structure as claimed in claim 7, wherein the P-type dopant comprises boron.

10. The pixel structure as claimed in claim 7, wherein the concentration of the N-type dopant is approximately in a range between 8×10¹² and 8×10¹⁶ atoms/cm³.

11. The pixel structure as claimed in claim 7, wherein the concentration of the P-type dopant is approximately in a range between 1×10¹³ and 1×10¹⁷ atoms/cm³.

12. The pixel structure as claimed in claim 1, further comprising a first insulating layer covering the gate electrode and the upper electrode.

13. The pixel structure as claimed in claim 12, further comprising a conductive layer on the first insulating layer, wherein the first insulating layer and the dielectric layer comprise a first opening to expose a portion of the active layer, and the conductive layer electrically connects the active layer via the first opening.

14. The pixel structure as claimed in claim 13, wherein the first insulating layer and the dielectric layer comprise a second opening to expose the lower electrode, and the conductive layer electrically connects the lower electrode via the second opening.

15. The pixel structure as claimed in claim 14, further comprising:
a second insulating layer disposed on the conductive layer and the first insulating layer, wherein the second insulating layer comprises a third opening to expose the conductive layer; and
a pixel electrode, disposed on the second insulating layer, for electrically connecting the conductive layer via the third opening.

16. The pixel structure as claimed in claim 13, further comprising:
a second insulating layer disposed on the conductive layer and the first insulating layer, wherein the second insulating layer comprises a third opening to expose the conductive layer; and
a pixel electrode, disposed on the second insulating layer, for electrically connecting the conductive layer via the third opening.

17. The pixel structure as claimed in claim 12, further comprising a conductive layer on the first insulating layer, wherein the first insulating layer and the dielectric layer comprise an opening to expose the lower electrode, and the conductive layer electrically connects the lower electrode via the opening.

18. The pixel structure as claimed in claim 12, further comprising:
a second insulating layer on the conductive layer and the first insulating layer, wherein the second insulating layer comprises a third opening to expose the conductive layer; and
a pixel electrode on the second insulating layer, electrically connecting the conductive layer via the third opening.

19. The pixel structure as claimed in claim 1, wherein the active layer and the lower electrode comprise poly silicon.

20. The pixel structure as claimed in claim 1, wherein the active layer and the lower electrode comprise amorphous silicon.

21. The pixel structure as claimed in claim 1, wherein the active layer further comprises an intermediate region, disposed between the source region and the drain region, having the first dopant.

22. The pixel structure as claimed in claim 1, wherein the source region and the drain region physically disconnect the lower electrode.

23. A pixel structure, comprising:
a thin film transistor, formed on a substrate, comprising a gate electrode and an active layer, wherein the active layer comprises a source region and a drain region; and
a capacitor, formed on the substrate, comprising a lower electrode and an upper electrode, wherein the source region and the drain region physically disconnect the lower electrode.

24. A method for fabricating a pixel structure, comprising:
forming a buffer layer on a substrate;
forming an active layer and a lower electrode on the buffer layer, wherein the active layer comprises a source region and a drain region;
doping a first dopant at the source region and the drain region and a second dopant at the lower electrode, wherein the first dopant and the second dopant are of different types;
forming a dielectric layer on the active layer and the lower electrode; and
forming at least one gate and an upper electrode on the dielectric layer, respectively corresponding to the active layer and the lower electrode.

25. The method as claimed in claim 24, wherein the first dopant is an N-type dopant and the second dopant is a P-type dopant.

26. The method as claimed in claim 25, wherein the N-type dopant comprises phosphorus.

27. The method as claimed in claim 25, wherein the P-type dopant comprises boron.

28. The method as claimed in claim 25, wherein the concentration of the N-type dopant is approximately in a range between 8×10¹² and 8×10¹⁶ atoms/cm³.

29. The method as claimed in claim 25, wherein the concentration of the P-type dopant is approximately in a range between 1×10¹³ and 1×10¹⁷ atoms/cm³.

30. The method as claimed in claim 24, wherein the first dopant is a P-type dopant and the second dopant is an N-type dopant.

31. The method as claimed in claim 30, wherein the N-type dopant comprises phosphorus.

32. The method as claimed in claim 30, wherein the P-type dopant comprises boron.

33. The method as claimed in claim 30, wherein the concentration of the N-type dopant is approximately in a range between 8×10¹² and 8×10¹⁶ atoms/cm³.

34. The method as claimed in claim 30, wherein the concentration of the P-type dopant is approximately in a range between 1×10¹³ and 1×10¹⁷ atoms/cm³.

35. The method as claimed in claim 24, wherein the step of forming the active layer and the lower electrode on the buffer layer comprises:
forming a semiconductor layer on the buffer layer; and
patterning the semiconductor layer and defining the active layer and the lower electrode, the active layer physically disconnecting the lower electrode.

36. The method as claimed in claim 24, wherein the step of forming the active layer and the lower electrode on the buffer layer comprises:
forming a semiconductor layer on the buffer layer; and
defining the active layer and the lower electrode on the semiconductor layer.

37. The method as claimed in claim 24, further comprising:
forming a first insulating layer on the gate electrode, the upper electrode, and the dielectric layer; and
forming a first opening and a second opening in the first insulating layer exposing the source region and the drain region.

38. The method as claimed in claim 37, further comprising forming a signal line and a conductive layer on the first insulating layer, electrically connecting the source region and the drain region via the first opening and the second opening.

39. The method as claimed in claim 38, further comprising forming a third opening in the first insulating layer to expose the lower electrode, the conductive layer electrically connecting the lower electrode via the third opening.

40. The method as claimed in claim 39, further comprising:
forming a second insulating layer on the signal line, the conductive layer, and the first insulating layer;
forming a fourth opening in the second insulating layer exposing the conductive layer; and
forming a pixel electrode on the second insulating layer, electrically connecting the conductive layer via the fourth opening.

41. The method as claimed in claim 38, further comprising:
forming a second insulating layer on the signal line, the conductive layer, and the first insulating layer;
forming a fourth opening in the second insulating layer exposing the conductive layer; and
forming a pixel electrode on the second insulating layer, electrically connecting the conductive layer via the fourth opening.

42. The method as claimed in claim 24, wherein the active layer further comprises an intermediate region disposed between the source region and the drain region and doped with the first dopant.

43. A method for fabricating a pixel structure, comprising:
forming a buffer layer on a substrate;
forming a semiconductor layer on the buffer layer;
patterning the semiconductor and defining an active layer and a lower electrode, the active layer comprising a source region and a drain region physically disconnecting the lower electrode;
forming a dielectric layer on the active layer and the lower electrode; and
forming at least one gate and an upper electrode on the dielectric layer, respectively corresponding to the active layer and the lower electrode.

44. The method as claimed in claim 43, further comprising doping the source region, the drain region and the lower electrode.

45. The method as claimed in claim 43, wherein the active layer further comprises an intermediate region disposed between the source region and the drain region.
